(19) United States
(12) Patent Application Publication
(10) Pub. No.: US 2026/0269816 A1
(43) Pub. Date: Sep. 10, 2026

(54) SIGNAL TRANSMISSION DEVICE HAVING CONTROLLABLE FEEDTHROUGH CANCELLATION MECHANISM AND SIGNAL TRANSMISSION METHOD THEREOF

(71) Applicant: REALTEK SEMICONDUCTOR CORPORATION, HSINCHU (TW)

(72) Inventor: SHIH-HSIUNG HUANG, Hsinchu (TW)

(21) Appl. No.: 19/541,437

(22) Filed: Feb. 17, 2026

(30) Foreign Application Priority Data
Mar. 6, 2025 (TW) 114108413

(51) Int. Cl. H03K 5/125; H03K 17/56

(52) U.S. Cl. CPC H03K 5/125; H03K 17/56

(57) ABSTRACT

A signal transmission device includes a main circuit and a feedthrough cancellation circuit. The main circuit is turned on to transmit a first input signal to a first output node and transmit a second input signal to a second output node. The feedthrough cancellation circuit couples the second input signal to the first output node via a first path and couples the first input signal to the second output node via a second path when the main circuit is turned off. Each of the first and the second paths includes a switch and a coupling circuit. The switch is turned on when the main circuit is turned off and is turned off when the main circuit is turned on. The coupling circuit is coupled in series to the switch and provides a capacitive element to couple a corresponding input signal to a corresponding output node.

### BACKGROUND OF THE INVENTION

### 1. Field of the Invention

The present disclosure relates to a signal transmission device, and more particularly to a signal transmission device having a controllable feedthrough cancellation mechanism and a signal transmission method thereof.

### 2. Description of Related Art

In existing signal transmission devices, when the main transmission path is turned off, an input signal may still erroneously be transmitted to an output node along parasitic elements on the main transmission path, affecting a signal level at the output node. Such a situation may cause errors in subsequent signal processing. To reduce the above problem, some related approaches employ a fixed coupling path to reduce an influence of the above parasitic elements. However, the fixed coupling path continuously adjusts the signal level at the output node, which instead reduces the precision and the gain of the transmitted signal when the transmission path is turned on.

### SUMMARY OF THE INVENTION

In some aspects, one of the objects of the present disclosure is (but is not limited to) providing a signal transmission device having a controllable feedthrough cancellation mechanism and a signal transmission method thereof, so as to make an improvement to the prior art.

In some aspects, a signal transmission device includes a main circuit and a feedthrough cancellation circuit. The main circuit is configured to be turned on according to a first clock signal to transmit a first input signal to a first output node and transmit a second input signal to a second output node. The feedthrough cancellation circuit is configured to, during a period in which the main circuit is turned off, couple the second input signal to the first output node via a first path and couple the first input signal to the second output node via a second path. Each of the first path and the second path includes a first switch and a coupling circuit. The first switch is configured to be turned on during the period in which the main circuit is turned off according to a second clock signal and turned off during a period in which the main circuit is turned on. The coupling circuit is connected in series to the first switch, and is configured to provide a capacitive element to couple a corresponding signal in the first input signal and the second input signal to a corresponding output node in the first output node and the second output node.

In some aspects, a signal transmission method includes the following operations: turning on a main circuit according to a first clock signal, in order to, via the main circuit, transmit a first input signal to a first output node and transmit a second input signal to a second output node; and during a period in which the main circuit is turned off, coupling the first input signal to the second output node via a first path in a feedthrough cancellation circuit and coupling the second input signal to the first output node via a second path in the feedthrough cancellation circuit, in which coupling the first input signal to the second output node via the first path includes: turning on a first switch in the first path during the period in which the main circuit is turned off according to a second clock signal; and providing a capacitive element via a coupling circuit in the first path to couple the first input signal to the second output node, wherein the coupling circuit is connected in series to the first switch.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1A is a schematic diagram of a signal transmission device according to some embodiments of the present disclosure.

FIG. 1B is a schematic diagram of waveforms of the clock signals of FIG. 1A according to some embodiments of the present disclosure.

FIG. 2 is a schematic diagram of a signal transmission device according to some embodiments of the present disclosure.

FIG. 3 is a schematic diagram of a signal transmission device according to some embodiments of the present disclosure.

FIG. 4 is a schematic diagram of a signal transmission device according to some embodiments of the present disclosure.

FIG. 5 is a flowchart of a signal transmission method according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuit” may indicate an object, which is formed with one or more transistors and/or one or more active/passive elements according to a specific arrangement, for processing signals.

As used herein, the term "and/or" includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, similar/identical elements in various figures are designated with the same reference number.

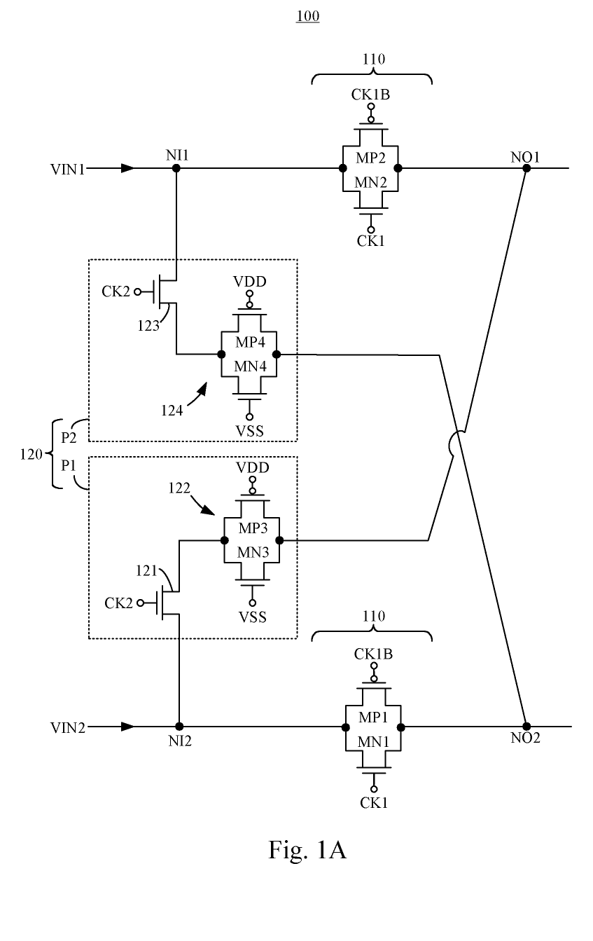

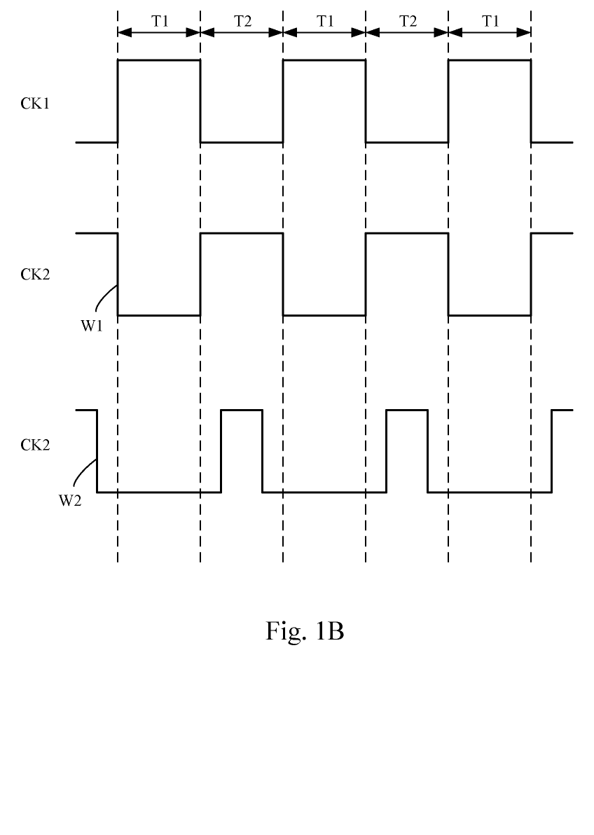

FIG. 1A is a schematic diagram of a signal transmission device 100 according to some embodiments of the present disclosure. In some embodiments, the signal transmission device 100 may be applied to signal sampling, but the present disclosure is not limited thereto. The signal transmission device 100 includes a main circuit 110 and a feedthrough cancellation circuit 120. The main circuit 110 is configured to be turned on according to a clock signal CK1 to transmit an input signal VIN1 to an output node NO1, and to transmit an input signal VIN2 to an output node NO2. Generally, a sampling circuit usually includes a switch and a capacitor, the switch is configured to determine a time point of signal sampling, that is, when the switch is turned on, the capacitor may sample the signal via the turned-on switch. In some embodiments, when the signal transmission device 100 is applied to the sampling circuit, the main circuit 110 may operate as a switch of the sampling circuit, and capacitors of the sampling circuit may be respectively coupled to the output node NO1 and the output node NO2 to sample the input signal VIN1 and the input signal VIN2 respectively. For example, when the main circuit 110 is turned on, the capacitors may receive the input signal VIN1 and the input signal VIN2 via the turned-on main circuit 110 to respectively store the input signal VIN1 on the output node NO1 and the input signal VIN2 on the output node NO2.

In some embodiments, the main circuit 110 includes a transistor MP1, a transistor MN1, a transistor MP2, and a transistor MN2. In this example, the transistor MP1 and the transistor MN1 operate as a transmission gate circuit, and the transistor MP2 and the transistor MN2 operate as another transmission gate circuit. In greater detail, a first terminal (e.g., a source/drain) of the transistor MP1 and a first terminal (e.g., a source/drain) of the transistor MN1 are coupled to an input node NI2 that provides the input signal VIN2, and a second terminal (e.g., a drain/source) of the transistor MP1 and a second terminal (e.g., a drain/source) of the transistor MN1 are coupled to the output node NO2. A control terminal (e.g., a gate) of the transistor MN1 receives a clock signal CK1, and a control terminal (e.g., a gate) of the transistor MP1 receives a clock signal CK1B. In some embodiments, the clock signal CK1 and the clock signal CK1B have opposite phases (that is, a phase of the clock signal CK1 and a phase of the clock signal CK1B are different by about 180 degrees). In some embodiments, the signal transmission device 100 may further include an inverter circuit (not shown) that generates the clock signal CK1B according to the clock signal CK1. With the above configuration, when the clock signal CK1 is at a high level, the clock signal CK1B is at a low level, such that transistor MP1 and transistor MN1 are turned on to transmit the input signal VIN2 to the output node NO2.

Similarly, a first terminal of the transistor MP2 and a first terminal of the transistor MN2 are coupled to an input node NI1 that provides the input signal VIN1, and a second terminal of the transistor MP2 and a second terminal of the transistor MN2 are coupled to the output node NO1. A control terminal of the transistor MN2 receives the clock signal CK1, and a control terminal of the transistor MP2 receives the clock signal CK1B. When the clock signal CK1 is at a high level, the clock signal CK1B is at a low level, such that the transistor MP2 and the transistor MN2 are turned on to transmit the input signal VIN1 to the output node NO1.

Ideally, when the main circuit 110 is turned off, the input signal VIN1 is not transmitted to the output node NO1, and the input signal VIN2 is not transmitted to the output node NO2. However, due to an influence of parasitic elements (which may be for example, but not limited to, parasitic capacitors between the first terminal and the second terminal of any of the above transistors) present in an actual circuit, the input signal VIN1 and the input signal VIN2 are still feedthrough (that is, coupled) to the output node NO1 and the output node NO2 via the above parasitic elements during the period in which the main circuit 110 is turned off, thereby reducing accuracy of signal sampling.

To improve the above problem, the feedthrough cancellation circuit 120 is configured to, during the period in which the main circuit 110 is turned off, couple the input signal VIN2 to the output node NO1 via the path P1 and couple the input signal VIN1 to the output node NO2 via the path P2. In some embodiments, the input signal VIN1 and the input signal VIN2 are differential signals. Therefore, when the main circuit 110 is turned off, the feedthrough cancellation circuit 120 may provide the input signal VIN2 to the output node NO1 via the path P1 to cancel the input signal VIN1 coupled via the parasitic elements. Similarly, when the main circuit 110 is turned off, the feedthrough cancellation circuit 120 may provide the input signal VIN1 to the output node NO2 via the path P2 to cancel the input signal VIN2 coupled via the parasitic elements. In other words, during the period in which the main circuit 110 is turned off, the feedthrough cancellation circuit 120 may be turned on according to the clock signal CK2 to perform the aforementioned feedthrough cancellation operation. On the other hand, to avoid the feedthrough cancellation circuit 120 affecting operation of the main circuit 110, the feedthrough cancellation circuit 120 is further configured to be turned off during the period in which the main circuit 110 is turned on.

For example, the path P1 includes a switch 121 and a coupling circuit 122. In some embodiments, the switch 121 may be implemented with, but not limited to, an N-type transistor. The switch 121 and the coupling circuit 122 are coupled in series and are coupled between the input node NI2 and the output node NO1. In greater detail, a first terminal of the switch 121 is coupled to the input node NI2 to receive the input signal VIN2, a second terminal of the switch 121 is coupled to the coupling circuit 122, and a control terminal of the switch 121 receives the clock signal CK2. The switch 121 may be selectively turned on according to the clock signal CK2. The switch 121 may be coupled to the output node NO1 via the coupling circuit 122. When the switch 121 is turned on, the switch 121 may provide the input signal VIN2 to the output node NO1 via the coupling circuit 122.

In some embodiments, a circuit structure of the coupling circuit 122 may be the same as a portion of a circuit structure of the main circuit 110 (e.g., the aforementioned transistor MP1 and the transistor MN1) to provide the same or similar parasitic element(s) (e.g., but not limited to, capacitive element(s)) to couple the input signal VIN2 to the output node NO1. For example, the coupling circuit 122 includes a transistor MP3 and a transistor MN3. A connection relationship between the transistor MP3 and the transistor MN3 is the same as a connection relationship between the transistor MP1 and the transistor MN1. In some embodiments, a size of the transistor MP3 may be the same as a size of the transistor MP1, and a size of the transistor MN3 may be the same as a size of the transistor MN1, but the present disclosure is not limited thereto. As mentioned above, the transistor MN1 and the transistor MP1 are configured to be turned on according to the clock signal CK1 and the clock signal CK1B (which is a logical inversion of the clock signal CK1). Different from the transistor MP1 and the transistor MN1, the transistor MN3 and the transistor MP3 are configured to not be turned on according to the bias voltage VSS and the bias voltage VDD. With the above configuration, the transistor MN3 may equivalently operate as the parasitic element presented by the transistor MN1 when the transistor MN1 is turned off, and the transistor MP3 may equivalently operate as the parasitic element presented by the transistor MP1 when the transistor MP1 is turned off.

Similarly, the path P2 includes a switch 123 and a coupling circuit 124. The switch 123 and the coupling circuit 124 are coupled in series and are coupled between the input node NI1 and the output node NO2. In some embodiments, the switch 123 may be implemented by, but not limited to, an N-type transistor. In greater detail, a first terminal of the switch 123 is coupled to the input node NI1 to receive the input signal VIN1, a second terminal of the switch 123 is coupled to the coupling circuit 124, and a control terminal of the switch 123 receives the clock signal CK2. The switch 123 may selectively be turned on according to the clock signal CK2. The switch 123 may be coupled to the output node NO2 via the coupling circuit 124. When the switch 123 is turned on, the switch 123 may provide the input signal VIN1 to the output node NO2 via the coupling circuit 124. In some embodiments, a circuit structure of the coupling circuit 124 may be the same as a portion of a circuit structure of the main circuit 110 (e.g., the aforementioned transistor MP2 and the transistor MN2) to provide the same or similar parasitic element(s) (e.g., but not limited to, capacitive element(s)) to couple the input signal VIN1 to the output node NO2. For example, the coupling circuit 124 includes a transistor MP4 and a transistor MN4. A connection relationship between the transistor MP4 and the transistor MN4 is the same as a connection relationship between the transistor MP2 and the transistor MN2. In some embodiments, a size of the transistor MP4 may be the same as a size of the transistor MP2, and a size of the transistor MN4 may be the same as a size of the transistor MN2, but the present disclosure is not limited thereto. As previously described, the transistor MN2 and the transistor MP2 are configured to be turned on according to the clock signal CK1 and the clock signal CK1B. Different from the transistor MN2 and the transistor MP2, the transistor MN4 and the transistor MP4 are configured not to be turned on according to the bias voltage VSS and the bias voltage VDD. With the above configuration, the transistor MN4 may equivalently operate as the parasitic element presented by the transistor MN2 when the transistor MN2 is turned off, and the transistor MP4 may equivalently operate as the parasitic element presented by the transistor MP2 when the transistor MP2 is turned off.

FIG. 1B is a schematic diagram of waveforms of the clock signal CK1 and the clock signal CK2 of FIG. 1A according to some embodiments of the present disclosure. As described above, during the period in which the main circuit 110 is turned off, the feedthrough cancellation circuit 120 couples the input signal VIN2 to the output node NO1 via the path P1 and couples the input signal VIN1 to the output node NO2 via the path P2. That is, the switch 121 in the path P1 and the switch 123 in the path P2 are configured to be turned on when the main circuit 110 is turned off.

For example, as shown in FIG. 1B, the main circuit 110 may be turned on during a period T1 in which the clock signal CK1 has a high level and may not be turned on during a period T2 in which the clock signal CK1 has a low level. Correspondingly, the switch 121 and the switch 123 may be configured not to be turned on during the aforementioned period T1 and to be turned on during the aforementioned period T2. As described above, the switch 121 and the switch 123 are configured to be turned on according to the clock signal CK2. In some embodiments, as shown in waveform W1, the clock signal CK2 and the clock signal CK1 have opposite phases. That is, when the clock signal CK1 has a high level, the clock signal CK2 has a low level; vice versa. In other embodiments, as shown in waveform W2, the clock signal CK1 and the clock signal CK2 may be non-overlapping clock signals, that is, there is a time difference between a falling edge of the clock signal CK1 and a rising edge of the clock signal CK2, and the same time difference exists between a rising edge of the clock signal CK1 and a falling edge of the clock signal CK2. With the above waveform setting, the feedthrough cancellation circuit 120 may be turned on according to the clock signal CK2 during the period T2 in which the main circuit 110 is turned off to perform feedthrough cancellation, and may not be turned on according to the clock signal CK2 during the period T1 in which the main circuit 110 is turned on to reduce influence on the main circuit 110.

In the signal transmission device 100, when a corresponding switch of the switches 121 and 123 is turned on, the corresponding switch provides, via a corresponding circuit in the coupling circuit 122 and the coupling circuit 124, a corresponding signal in the input signal VIN2 and the input signal VIN1 to a corresponding output node in the output node NO1 and the output node NO2. That is, in the signal transmission device 100, the aforementioned corresponding circuit is further configured to receive the corresponding signal and to be coupled to the corresponding output node via the corresponding coupling circuit. For example, when the switch 121 is turned on, the switch 121 may provide the input signal VIN2 to the output node NO1 via the coupling circuit 122.

In some embodiments, the clock signal CK1 and/or the clock signal CK2 may have a duty cycle of about 50%, but the present disclosure is not limited thereto. Clock signals CK1 and/or CK2 having duty cycles of various values are within the contemplated scope of the present disclosure.

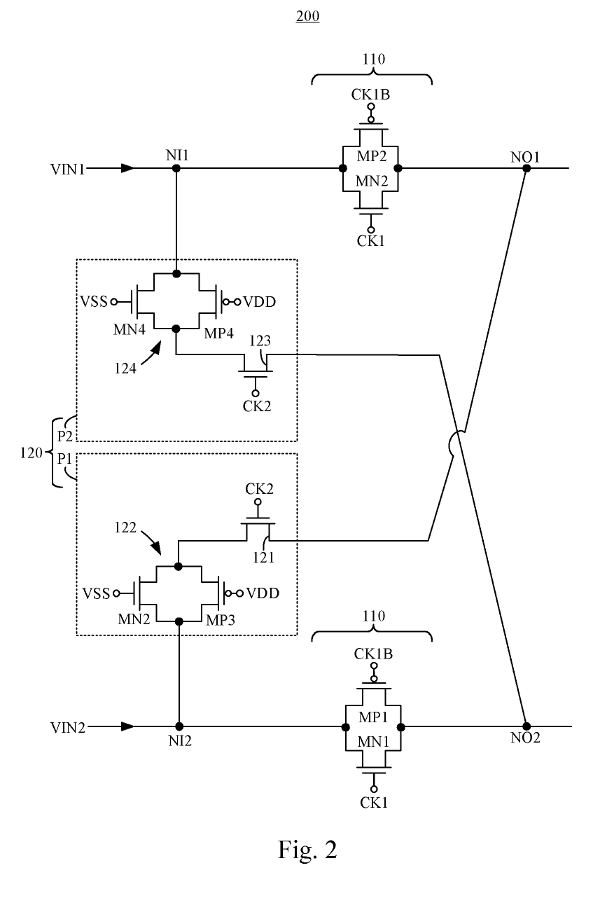

FIG. 2 is a schematic diagram of a signal transmission device 200 according to some embodiments of the present disclosure. Different from FIG. 1A, in the signal transmission device 200, the coupling circuit 122 is coupled between the input node NI2 and the switch 121, and the coupling circuit 124 is coupled between the input node NI1 and the switch 123. In greater detail, in this example, the coupling circuit 122 is coupled to the input node NI2 to receive the input signal VIN2 and is coupled to the output node NO1 via the switch 121. Similarly, the coupling circuit 124 is coupled to the input node NI1 to receive the input signal VIN1 and is coupled to the output node NO2 via the switch 123.

In other words, in the example of FIG. 2, when a corresponding switch of the switches 121 and 123 is turned on, a corresponding circuit in the coupling circuit 122 and the coupling circuit 124 may provide the input signal VIN2 and the input signal VIN1 to a corresponding output node in the output node NO1 and the output node NO2 via the corresponding switch. For example, when the switch 121 is turned on, the coupling circuit 122 may provide the input signal VIN2 to the output node NO1 via the switch 121. When the switch 123 is turned on, the coupling circuit 124 may provide the input signal VIN1 to the output node NO2 via the switch 123.

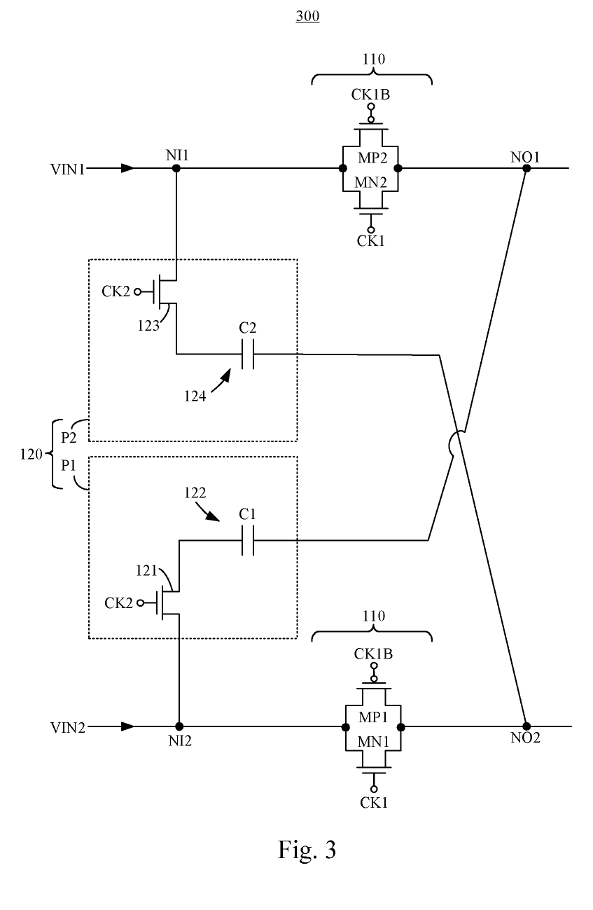

FIG. 3 is a schematic diagram of a signal transmission device 300 according to some embodiments of the present disclosure. Different from FIG. 1A, in the signal transmission device 300, the coupling circuit 122 may be a capacitor C1 to serve as the aforementioned capacitive element to couple the input signal VIN2 to the output node NO1. Similarly, the coupling circuit 124 may be a capacitor C2 to serve as the aforementioned capacitive element to couple the input signal VIN1 to the output node NO2.

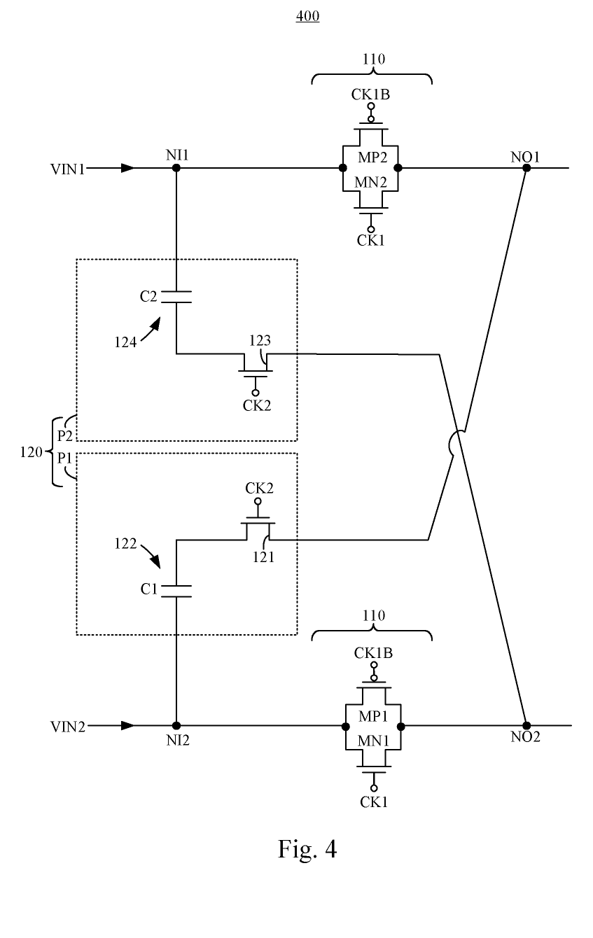

FIG. 4 is a schematic diagram of a signal transmission device 400 according to some embodiments of the present disclosure. Similarly, different from FIG. 2, in the signal transmission device 400, the coupling circuit 122 may be a capacitor C1 to serve as the aforementioned capacitive element to couple the input signal VIN2 to the output node NO1 via the switch 121. Similarly, the coupling circuit 124 may be a capacitor C2 to serve as the aforementioned capacitive element to couple the input signal VIN1 to the output node NO2 via the switch 123. The coupling circuit 122 receives the input signal VIN2 and is coupled to the output node NO1 via the switch 121, and the coupling circuit 124 receives the input signal VIN1 and is coupled to the output node NO2 via the switch 123.

In the above embodiments, the switch 121 and the switch 123 are implemented with N-type transistors, but the present disclosure is not limited thereto. Depending on practical needs, the switch 121 and the switch 123 may also be implemented with transistors having other conductivity types. On the other hand, for illustrative purposes, in the above embodiments, the main circuit 110 is implemented with a transmission gate circuit, but the present disclosure is not limited thereto. Depending on practical needs, the main circuit 110 may also be implemented with other types of switching circuits. Accordingly, implementations of the coupling circuit 122 and the coupling circuit 124 may also be correspondingly adjusted. Therefore, corresponding configurations in FIGS. 1A, 2, 3 and 4 are given for illustrative purposes only and the present disclosure is not limited thereto.

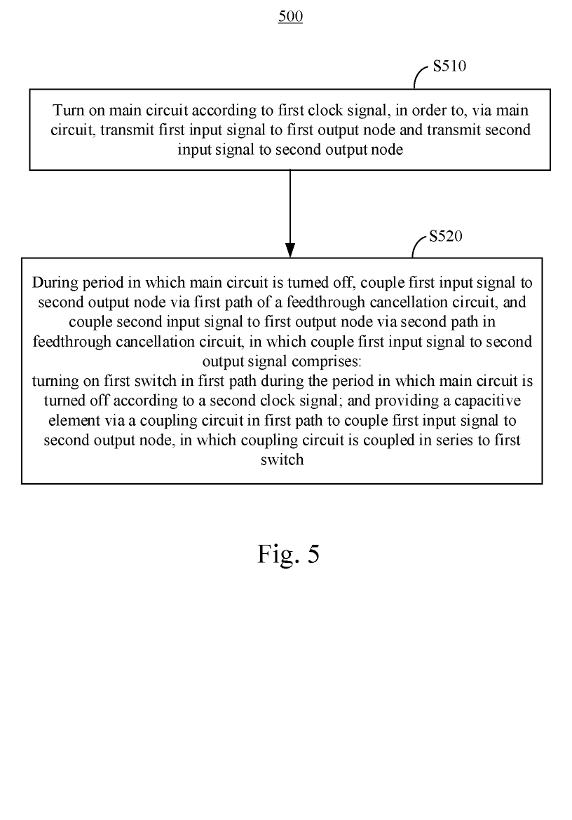

FIG. 5 is a flowchart of a signal transmission method 500 according to some embodiments of the present disclosure. In different embodiments, the signal transmission method 500 may be performed by any of the aforementioned signal transmission devices 100, 200, 300 or 400, but the present disclosure is not limited thereto.

In operation S510, a main circuit is turned on according to a first clock signal, in order to, via the main circuit, transmit a first input signal to a first output node and transmit a second input signal to a second output node. In operation S520, during the period in which the main circuit is turned off, a first path in a feedthrough cancellation circuit couples the first input signal to the second output node, and a second path in the feedthrough cancellation circuit couples the second input signal to the first output node, in which coupling the first input signal to the second output node via the first path includes: turning on a first switch in the first path during the period in which the main circuit is turned off according to a second clock signal; and providing a capacitive element via a coupling circuit in the first path to couple the first input signal to the second output node, in which the coupling circuit is coupled in series to the first switch.

The related operations of the signal transmission method 500 may refer to the descriptions of the aforementioned embodiments and therefore will not be repeated here. Operations in the signal transmission method 500 include exemplary operations, but the operations in the signal transmission method 500 are not necessarily performed in the order described above. Operations in the signal transmission method 500 may be added, replaced, changed order, and/or eliminated, or one or more operations in the signal transmission method 500 may be executed simultaneously or partially simultaneously as appropriate, in accordance with the spirit and scope of various embodiments of the present disclosure.

As described above, the signal transmission devices and the signal transmission methods provided in some embodiments of the present disclosure may utilize a feedthrough cancellation circuit to reduce influence of parasitic elements and utilize an additional switching mechanism to prevent the feedthrough cancellation circuit from affecting signal transmission operations of the main circuit.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically include transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely some embodiments of the present disclosure, without any intention to limit the scope of the present disclosure thereto. Various equivalent changes, alterations, or modifications according to the claims of present disclosure are all consequently viewed as being embraced by the scope of the present disclosure.

What is claimed is:

1. A signal transmission device, comprising:
a main circuit configured to be turned on according to a first clock signal to transmit a first input signal to a first output node and transmit a second input signal to a second output node; and
a feedthrough cancellation circuit configured to, during a period in which the main circuit is turned off, couple the second input signal to the first output node via a first path and couple the first input signal to the second output node via a second path,
wherein each of the first path and the second path comprises:
a first switch configured to be turned on during the period in which the main circuit is turned off according to a second clock signal and turned off during a period in which the main circuit is turned on; and
a coupling circuit, connected in series to the first switch, and configured to provide a capacitive element to couple a corresponding signal in the first input signal and the second input signal to a corresponding output node in the first output node and the second output node.

2. The signal transmission device according to claim 1, wherein when the first switch is turned on, the first switch provides the corresponding signal to the corresponding output node via the coupling circuit.

3. The signal transmission device according to claim 1, wherein the first switch is further configured to receive the corresponding signal and be coupled to the corresponding output node via the coupling circuit.

4. The signal transmission device according to claim 1, wherein when the first switch is turned on, the coupling circuit provides the corresponding signal to the corresponding output node via the first switch.

5. The signal transmission device according to claim 1, wherein the coupling circuit is further configured to receive the corresponding signal and be coupled to the corresponding output node via the first switch.

6. The signal transmission device according to claim 1, wherein the coupling circuit is a capacitor.

7. The signal transmission device according to claim 1, wherein each of the main circuit and the coupling circuit comprises a plurality of transistors, the plurality of transistors in the main circuit are configured to be turned on according to the first clock signal, and the plurality of transistors in the coupling circuit are configured to be turned off according to a plurality of bias voltages.

8. The signal transmission device according to claim 7, wherein the plurality of transistors in the main circuit are configured to operate as a transmission gate circuit.

9. The signal transmission device according to claim 1, wherein the first clock signal and the second clock signal have opposite phases.

10. The signal transmission device according to claim 1, wherein the first clock signal and the second clock signal are non-overlapping clock signals.

11. A signal transmission method, comprising:
turning on a main circuit according to a first clock signal, in order to, via the main circuit, transmit a first input signal to a first output node and transmit a second input signal to a second output node; and
during a period in which the main circuit is turned off, coupling the first input signal to the second output node via a first path in a feedthrough cancellation circuit and coupling the second input signal to the first output node via a second path in the feedthrough cancellation circuit,
wherein coupling the first input signal to the second output node via the first path comprises:
turning on a first switch in the first path during the period in which the main circuit is turned off according to a second clock signal; and
providing a capacitive element via a coupling circuit in the first path to couple the first input signal to the second output node, wherein the coupling circuit is connected in series to the first switch.

12. The signal transmission method according to claim 11, wherein when the first switch is turned on, the first switch provides the first input signal to the second output node via the coupling circuit.

13. The signal transmission method according to claim 11, wherein the first switch is further configured to receive the first input signal and be coupled to the second output node via the coupling circuit.

14. The signal transmission method according to claim 11, wherein when the first switch is turned on, the coupling circuit provides the first input signal to the second output node via the first switch.

15. The signal transmission method according to claim 11, wherein the coupling circuit is further configured to receive the first input signal and be coupled to the second output node via the first switch.

16. The signal transmission method according to claim 11, wherein the coupling circuit is a capacitor.

17. The signal transmission method according to claim 11, wherein each of the main circuit and the coupling circuit comprises a plurality of transistors, the plurality of transistors in the main circuit are configured to be turned on according to the first clock signal, and the plurality of transistors in the coupling circuit are configured to be turned off according to a plurality of bias voltages.

18. The signal transmission method according to claim 17, wherein the transistors in the main circuit are configured to operate as a transmission gate circuit.

19. The signal transmission method according to claim 11, wherein the first clock signal and the second clock signal have opposite phases.

20. The signal transmission method according to claim 11, wherein the first clock signal and the second clock signal are non-overlapping clock signals.
